(19) United States
(12) Patent Application Publication
(10) Pub. No.: US 2026/0047008 A1
(43) Pub. Date: Feb. 12, 2026

(54) MEMORY MODULE AND A SYSTEM BOARD

(71) Applicants: Xiang LI, Portland, OR (US); Todd Andrew HINCK, Arlington, MA (US); James Alexander MCCALL, Portland, OR (US); George VERGIS, Portland, OR (US); Saravanan SETHURAMAN, Portland, OR (US)

(72) Inventors: Xiang LI, Portland, OR (US); Todd Andrew HINCK, Arlington, MA (US); James Alexander MCCALL, Portland, OR (US); George VERGIS, Portland, OR (US); Saravanan SETHURAMAN, Portland, OR (US)

(21) Appl. No.: 19/361,033

(22) Filed: Oct. 17, 2025

(51) Int. Cl. H05K 1/18

(52) U.S. Cl. CPC H05K 1/18; H05K 2201/10159; H05K 2201/10325; H05K 2201/10545

(57) ABSTRACT

Provided is memory module comprising a printed circuit board (PCB) having a first surface and a second surface opposite the first surface, and a connector edge comprising a set of electrical contacts configured for insertion into a memory socket. The memory module further comprises a plurality of memory devices and a first buffer component and a second buffer component. The PCB comprises a first and a second signal routing layer respectively associated with the first and second surfaces, each signal routing layer comprising a control signal input line from the set of electrical contacts to the respective buffer component, control signal output lines from the buffer component to the plurality of memory devices, and data signal lines from the set of electrical contacts to the plurality of memory devices.

### BACKGROUND

Memory systems in computing environments may require high-density configurations and rapid data access to meet performance demands in several applications. Some memory modules may utilize established form factors with standardized dimensions and component arrangements that position memory devices and buffer components at various locations on printed circuit boards. These modules may connect to system boards through edge connectors that establish electrical pathways between memory components and processors. Some memory architectures may face constraints related to signal routing complexity, printed circuit board layer requirements, or space utilization within equipment rack form factors.

### BRIEF DESCRIPTION OF THE FIGURES

Some examples of apparatuses and/or methods will be described in the following by way of example only, and with reference to the accompanying figures, in which

FIG. 1 illustrates a first example of a memory module;

FIG. 2 illustrates a second example of a memory module;

FIG. 3 illustrates the layout of a registered clock driver (RCD) component;

FIG. 4 illustrates a memory device;

FIG. 5 illustrates a cross-sectional view of a memory device;

FIG. 6 illustrates a system board comprising a plurality of memory sockets;

FIG. 7 illustrates a memory socket connection system;

FIG. 8 illustrates a memory module;

FIG. 9 illustrates a DDR5 system;

FIG. 10 illustrates a system board;

FIG. 11 illustrates an equipment rack; and

FIG. 12 illustrates a computing device in accordance with one implementation of the disclosed memory module.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, i.e. only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

In the following description, specific details are set forth, but examples of the technologies described herein may be practiced without these specific details. Well-known circuits, structures, and techniques have not been shown in detail to avoid obscuring an understanding of this description. “An example/example,” “various examples/examples,” “some examples/examples,” and the like may include features, structures, or characteristics, but not every example necessarily includes the particular features, structures, or characteristics.

Some examples may have some, all, or none of the features described for other examples. “First,” “second,” “third,” and the like describe a common element and indicate different instances of like elements being referred to. Such adjectives do not imply element item so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact.

As used herein, the terms “operating”, “executing”, or “running” as they pertain to software or firmware in relation to a system, device, platform, or resource are used interchangeably and can refer to software or firmware stored in one or more computer-readable storage media accessible by the system, device, platform, or resource, even though the instructions contained in the software or firmware are not actively being executed by the system, device, platform, or resource.

The description may use the phrases “in an example/example,” “in examples/examples,” “in some examples/examples,” and/or “in various examples/examples,” each of which may refer to one or more of the same or different examples. Furthermore, the terms “comprising,” “including,” “having,” and the like, as used with respect to examples of the present disclosure, are synonymous.

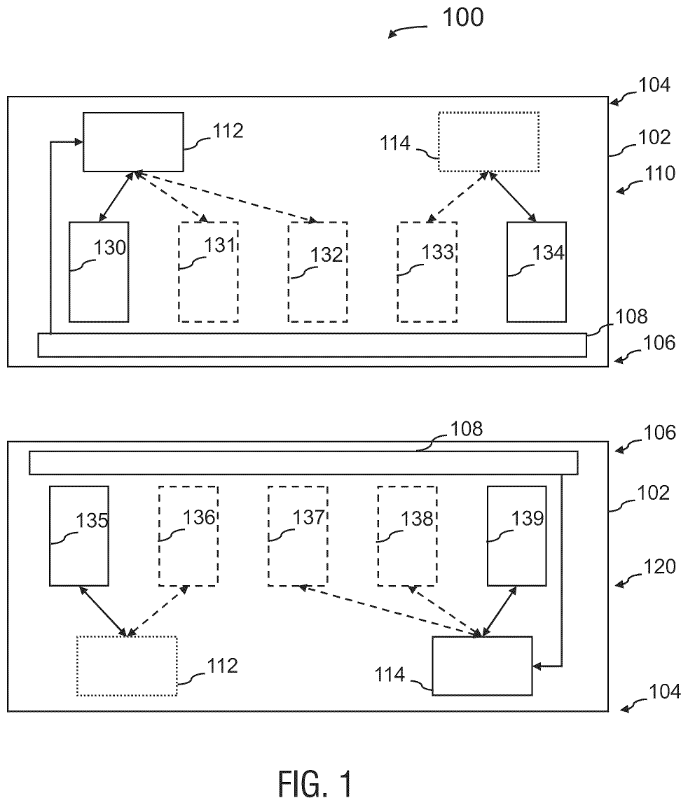

FIG. 1 illustrates a first example of a memory module 100. The memory module 100 comprises a printed circuit board (PCB) 102 having a first surface 110 and a second surface 120 opposite the first surface 110. The PCB 102 comprises a connector edge 106 comprising a set of electrical contacts 108 configured for insertion into a memory socket. For example, the memory module 100 may be a removable electronic assembly that serves as a primary data storage and retrieval component in computing systems. The memory module 100 may provide temporary storage for data and program instructions during system operation. The memory modules may be implemented as a dual inline memory module (DIMM) which feature dynamic random access memory chips arranged on both sides of the PCB. The memory module may be implemented as registered dual inline memory module (RDIMM) which incorporate register clock driver circuits enabling support for larger memory capacities and improved signal integrity in server and workstation applications. In some examples, the memory module may be implemented as small outline dual inline memory module (SODIMM) designed for space-constrained applications such as laptops and embedded systems. The memory module may provide standardized form factors and electrical interfaces that allow system designers to scale memory capacity by installing multiple modules in parallel memory channels. The memory module may enable users to upgrade system performance by replacing existing modules with higher-capacity or faster-speed variants without requiring motherboard modifications.

For example, the printed circuit board (PCB) 102 may be a multi-layered substrate that provides both mechanical support and electrical connectivity for electronic components mounted on the memory module 100. The PCB 102 may comprise multiple conductive layers formed for example from copper foil and separated by insulating materials such as fiberglass-reinforced epoxy resin, polyimide films, or ceramic substrates depending on the performance requirements. The PCB 102 may feature conductive traces that carry electrical signals, power planes that distribute supply voltages, and ground planes that provide reference potentials and electromagnetic shielding. The PCB 102 may include contact pads, via structures, and/or solder mask layers that facilitate component mounting and electrical connections between the first surface 110 and the second surface 120.

The PCB 102 may incorporate through-hole vias that provide electrical connections between all layers, blind vias that connect surface layers to internal layers, and buried vias that connect only internal layers to optimize signal routing density and minimize electromagnetic interference. The PCB 102 may have a rigid construction with controlled impedance characteristics that maintains dimensional stability under thermal cycling and mechanical stress during operation. The PCB 102 may provide mounting locations for memory devices, buffer components, power management circuits, and passive components through surface-mount technology pads, ball grid array patterns, or through-hole connections. The PCB 102 may enable high-density component placement on both the first surface 110 and second surface 120 while maintaining signal integrity through controlled trace lengths and layer stackup optimization within the standardized memory module form factor constraints.

For example, the connector edge 106 may be a specifically designed portion of the PCB 102 that enables physical and electrical connection between the memory module 100 and a memory socket on a host system motherboard. The connector edge 106 may extend along one edge of the PCB 102 and feature a standardized thickness and profile that allows insertion into a corresponding memory socket with spring-loaded contacts. The connector edge 106 may provide mechanical guidance during insertion and ensure proper alignment between the electrical contacts 108 on the memory module 100 and the socket contacts in the memory socket. The connector edge 106 may include chamfered edges or tapered profiles that facilitate smooth insertion and reduce the risk of contact damage during installation.

For example, the electrical contacts 108 may comprise a plurality of conductive elements arranged along the connector edge 106 that establish electrical pathways between components on the memory module 100 and the host system circuitry. The set of electrical contacts 108 may include in some dozens or hundreds of individual contact points depending on the memory interface specification and data width requirements. The electrical contacts 108 may comprise gold-plated copper traces, contact pads, or edge fingers that provide reliable electrical connections with low contact resistance and corrosion protection. The electrical contacts 108 may carry various signal types including data signals, address signals, control signals, clock signals, and power supply voltages required for memory operation. The electrical contacts 108 may be arranged in standardized patterns and pitch spacing that correspond to industry specifications for memory module interfaces such as DDR4, DDR5, or DDR6 protocols.

The electrical contacts 108 may be manufactured through various processes and configurations to optimize electrical performance and mechanical durability. In some examples, the electrical contacts 108 may be formed as flush-mounted contact pads that may lie substantially flat with the PCB 102 surface and provide smooth contact surfaces for socket engagement. The electrical contacts 108 may alternatively be implemented as raised contact bumps that extend above the PCB 102 surface to ensure positive contact pressure with socket springs. The electrical contacts 108 may feature beveled edges or rounded profiles that reduce wear during repeated insertion and removal cycles. In some examples, the electrical contacts 108 may include multiple plating layers such as a nickel barrier layer beneath a gold contact surface to prevent copper diffusion and maintain long-term contact reliability.

The memory module 100 further comprises a plurality of memory devices mounted on each of the first 110 and second surface 120 of the PCB 102. For example, the memory module 100 comprises two memory devices on each surface of the PCB 102 (for example memory devices 130, 134 on the first surface 110 of the PCB and memory modules 135, 139 on the second surface 120 of the PCB). In some examples, the memory module 100 comprises three or four or five or more memory devices on each surface sides of the PCB 102 (for example memory devices 130, 131, 132, 133, 134 on the first surface 110 of the PCB and memory modules 135, 136, 137, 138, 139 on the second surface 120 of the PCB).

For example, the memory devices may be integrated circuit packages that contain memory storage elements capable of storing and retrieving digital data. The memory devices may comprise semiconductor chips housed within protective packaging that provides electrical connections to the PCB 102 through a mounting technology. The memory devices may include multiple memory cells organized into addressable locations that can be accessed through control signals and data pathways. The memory devices may provide temporary data storage during system operation and may be capable of high-speed read and write operations to support processor data requirements.

The memory devices may be mounted on both the first surface 110 and second surface 120 of the PCB 102 to maximize memory capacity within the available form factor constraints. The memory devices may be attached to the PCB 102 through surface-mount technology using ball grid array connections, land grid array connections, or quad flat no-leads packages that provide reliable electrical and mechanical attachment. The memory devices may be soldered to contact pads on the PCB 102 using reflow soldering processes that create permanent electrical connections between package terminals and PCB traces. The memory devices may be positioned strategically on the PCB 102 to optimize electrical signal paths and minimize routing complexity between the memory devices and other components. The memory devices may be arranged in various configurations depending on the desired memory capacity, data width, and electrical performance requirements of the memory module 100.

For example, the plurality of memory devices may be arranged in linear configurations along the length of the PCB 102, positioned in parallel rows on the first and second surfaces 110, 120. In some examples, the plurality of memory devices may be distributed in grid patterns to optimize space utilization and electrical performance. The plurality of memory devices on the first surface 110 may be aligned directly opposite to memory devices on the second surface 120 to share common routing paths and minimize PCB layer requirements. The memory devices may alternatively be offset or staggered between the first surface 110 and second surface 120 to minimize electromagnetic interference between adjacent devices and improve thermal dissipation. The memory devices may be positioned strategically on the PCB 102 to optimize electrical signal paths and minimize routing complexity between the memory devices and other components such as buffer circuits or power management components.

In some examples, the memory devices may be dynamic random-access memory (DRAM). DRAM devices store data in capacitive memory cells requiring periodic refresh operations to maintain data integrity. The DRAM devices may comprise arrays of memory cells organized into banks, rows, and columns that can be accessed through row and column address signals. The DRAM devices may provide volatile storage that loses stored data when power is removed but offers high storage density and fast access times suitable for system memory applications. The DRAM devices may include on-chip refresh circuitry and timing control logic that manages the periodic refresh cycles required to preserve stored data.

The memory devices may be configured for operation according to a double data rate (DDR) memory protocol. A DDR memory protocol may transfer data on both rising and falling edges of the clock signal to achieve higher data throughput. The memory devices may support DDR4 protocols that provide data rates up to 3200 megatransfers per second with improved power efficiency and signal integrity features. The memory devices may support DDR5 protocols that enable data rates up to 6400 megatransfers per second with enhanced error correction capabilities and on-die error correction code features. The memory devices may support DDR6 protocols that achieve even higher data rates with advanced power management and signal integrity optimizations for next-generation computing applications. The memory devices may include protocol-specific features such as training sequences, calibration modes, and power management states that optimize performance for the particular DDR specification.

The memory module 100 may be implemented as a registered dual inline memory module (RDIMM). A RDIMM may incorporate buffer components to improve signal integrity and enable support for larger memory capacities in server and workstation applications. The RDIMM configuration may provide registered clock and control signals that reduce electrical loading on the memory controller and enable stable operation with multiple memory modules installed in parallel channels. The RDIMM may include error checking and correction capabilities that detect and correct single-bit errors and detect multi-bit errors to improve system reliability in mission-critical applications.

The memory module 100 further comprises a first buffer component 112 mounted on the first surface 110 and electrically coupled to a first subset of the memory devices located on the first surface 110 (for example 130, or 130, 131, 132) and the second surface 120 (for example 135, or 135, 136) of the PCB 102. The memory module 100 further comprises a second buffer component 114 mounted on the second surface 120 and electrically coupled to a second subset of the memory devices located on the first surface 110 (for example 134, or 133, 134) and the second surface 120 (for example 139, or 137, 138, 139) of the PCB 102. In some examples, the memory module 100 may comprise two or more buffer components mounted on each of the surfaces 110, 120 of the PCB 102.

For example, each of the buffer components may be an integrated circuit that receives, processes, and retransmits electrical signals between a memory controller and memory devices to improve signal integrity and system performance. The buffer component may amplify weak signals, restore signal timing characteristics, and provide electrical isolation between different circuit sections to prevent signal degradation over long routing paths. The buffer component may include register circuits that latch control signals and address information before forwarding them to memory devices, thereby reducing electrical loading on the memory controller and enabling support for larger numbers of memory devices. The buffer component may incorporate clock management circuits that generate clean clock signals with controlled timing relationships to ensure proper data transfer synchronization between the memory controller and memory devices.

The first buffer component 112 and second buffer component 114 may be electrically coupled to memory devices on both the first surface 110 and second surface 120 through conductive traces and via structures within the PCB 102. The electrical coupling may be accomplished using internal PCB layers that route signals from buffer components through via connections to memory devices on the opposite surface without interfering with surface-mounted components. The buffer components may connect to memory devices on the same surface through direct surface traces and to memory devices on the opposite surface through blind vias or buried vias that traverse the PCB thickness.

In other words, in some examples, each buffer component may be electrically coupled to at least one memory device mounted on the surface of the PCB opposite to the surface on which the buffer component is mounted. This mounting may create cross-surface electrical connections that optimize signal distribution and electrical loading. The first buffer component 112 mounted on the first surface 110 may be electrically coupled to at least one memory device mounted on the second surface 120, while the second buffer component 114 mounted on the second surface 120 may be electrically coupled to at least one memory device mounted on the first surface 110. This cross-surface coupling may be accomplished through via structures, buried vias, or blind vias within the PCB 102 that provide electrical pathways between the buffer components and memory devices on opposite surfaces. The cross-surface electrical coupling may enable balanced signal distribution and may reduce the total routing complexity by allowing buffer components to serve memory devices regardless of their surface location.

In some examples, each buffer component may be electrically coupled to the memory device located nearest to the buffer component on the opposite surface. This coupling may create optimized routing paths that minimize signal transmission distances for cross-surface connections. The first buffer component 112 mounted on the first surface 110 may be electrically coupled to the memory device on the second surface 120 that is positioned closest to the first buffer component 112, thereby minimizing the via length and routing distance required for the cross-surface electrical connection. The second buffer component 114 mounted on the second surface 120 may be electrically coupled to the memory device on the first surface 110 that is positioned closest to the second buffer component 114. This nearest-neighbor coupling approach may reduce signal propagation delays and minimize electromagnetic interference between cross-surface connections by utilizing the shortest possible electrical pathways between buffer components and their associated memory devices on opposite surfaces, while maintaining proper electrical loading distribution across all memory devices in the memory module 100.

This cross-surface electrical coupling between buffer components and memory devices may serve multiple technical purposes including load balancing, signal integrity optimization, and routing efficiency. The buffer components may distribute control signals and clock signals to memory devices on both surfaces to ensure uniform signal timing and reduce skew between memory devices that must operate synchronously. The cross-surface coupling may enable each buffer component to manage a subset of memory devices regardless of their physical surface location, allowing for more flexible memory organization and optimized electrical loading distribution. This configuration may reduce the total number of signal layers required in the PCB 102 by enabling shared routing paths and may minimize electromagnetic interference between adjacent memory devices through strategic signal distribution patterns that avoid signal crowding on any single surface. The cross-surface routing may provide design flexibility that enables better overall signal routing optimization even though individual signal paths may be longer due to the via transitions required.

In some examples, each buffer component may comprise a control signal input and a plurality of control signal outputs, each control signal output being coupled to a respective memory device. For example, each buffer component may comprise a control signal input and a plurality of control signal outputs that provide signal buffering and distribution functionality for the memory module 100. The buffer component may receive control signals, address signals, and clock signals from the memory controller through the control signal input and regenerate these signals with improved drive strength and timing characteristics at the plurality of control signal outputs. Each control signal output may be electrically coupled to a respective memory device to provide dedicated signal paths that minimize electrical loading and signal interference between different memory devices. The buffer component may include signal conditioning circuits that restore signal amplitude, reduce noise, and compensate for signal distortion that may occur during transmission from the memory controller to the memory module 100.

The plurality of control signal outputs may enable the buffer component to drive multiple memory devices simultaneously while maintaining signal integrity and timing precision required for high-speed memory operation. Each control signal output may provide buffered versions of control signals such as row address strobe signals, column address strobe signals, write enable signals, and chip select signals that coordinate memory device operations. The buffer component may include internal timing circuits that ensure proper setup and hold times for control signals relative to clock signals at each control signal output. The buffer component may provide electrical isolation between the control signal input and each control signal output to prevent signal reflections and crosstalk that could degrade system performance when multiple memory devices are operating simultaneously.

In some examples, the least one of the buffer components may be a registered clock driver (RCD). For example, the RCD may provide specialized signal buffering and clock distribution functionality for registered memory modules. The RCD may receive control signals, address signals, and clock signals from the memory controller and register these signals in internal latches or flip-flops before retransmitting them to the memory devices with improved signal integrity and reduced electrical loading. The RCD may include clock generation and distribution circuits that produce clean, low-jitter clock signals with controlled timing relationships to ensure proper synchronization between control signals and data transfers. The RCD may provide electrical isolation between the memory controller and the memory devices, enabling support for larger numbers of memory devices and higher memory capacities than would be possible with direct controller-to-memory connections.

The RCD may incorporate address and control signal registration that introduces a one-clock-cycle delay between signal reception and retransmission to improve signal quality and system stability. The RCD may include multiple independent clock domains and signal conditioning circuits that optimize signal timing and amplitude for different types of memory devices and operating frequencies. The RCD may provide error detection and correction capabilities for control and address signals to improve system reliability in server and workstation applications where data integrity is critical. The RCD may enable the memory module 100 to operate as a registered dual inline memory module (RDIMM) that supports higher memory densities and improved electrical performance compared to unbuffered memory module configurations.

The memory devices on the first 110 and second surfaces 120 are positioned adjacent to the connector edge 104 of the PCB 102, and the first 112 and second buffer components 114 are positioned at an edge 106 opposite the connector edge 104 on the PCB 102. For example, this positioning arrangement may create a layout where the memory devices may be clustered near one end of the PCB 102 at the connector edge 104, while the buffer components are located at the opposite end of the PCB 102 at the opposite edge 106. The memory devices may be arranged in a row or multiple rows running parallel to the connector edge 104, with the memory devices being the first components encountered when moving inward from the connector edge 104 toward the center of the PCB 102. The buffer components may be positioned near the opposite end of the PCB 102, with each buffer component having a control signal input that receives control signals, address signals, and clock signals from the electrical contacts 108, and a plurality of control signal outputs that connect to respective memory devices on both the first surface 110 and second surface 120.

This positioning arrangement may enable optimized PCB routing by allowing different signal types to share the same routing layers and significantly reduce the total number of PCB layers required. The placement may actually reduce the routing distance between buffer components and the memory devices they serve compared to other configurations, for example where buffer components are positioned in the same row as the memory devices, since the buffer components can connect more directly to memory devices distributed across both surfaces through their plurality of control signal outputs. The placement of memory devices adjacent to the connector edge 104 may minimize the routing distance for data signals traveling directly from the electrical contacts 108 to the memory device data terminals. The placement of buffer components at the opposite edge 106 may enable control signals to route from the electrical contacts 108 to the control signal input of each buffer component along one side of the memory devices, while the control signal outputs from the buffer components route to the respective memory devices along the opposite side. This spatial organization may allow data signals, control input signals, and control output signals to utilize the same routing layer without interference, thereby reducing PCB layer count requirements and manufacturing costs while maintaining signal integrity performance.

The PCB 102 comprises a first and a second signal routing layer respectively associated with the first surface 110 and second surface 120. Each signal routing layer comprises a control signal input line from the set of electrical contacts 108 to the respective buffer component 112, 114, control signal output lines from the buffer component 112, 114 to the plurality of memory devices, and data signal lines from the set of electrical contacts 108 to the plurality of memory devices.

For example, the first signal routing layer may be positioned within the PCB 102 structure and associated with the first surface 110 to provide electrical pathways for signals related to components mounted on the first surface 110. The first signal routing layer may include control signal input lines that carry control signals, address signals, and clock signals from specific electrical contacts 108 at the connector edge 104 to the control signal input of the first buffer component 112 mounted on the first surface 110. The first signal routing layer may include control signal output lines that carry buffered and registered control signals from the plurality of control signal outputs of the first buffer component 112 to respective memory devices in the first subset, including memory devices mounted on both the first surface 110 and second surface 120 that are served by the first buffer component 112. The first signal routing layer may include data signal lines that provide direct electrical pathways from data-related electrical contacts 108 at the connector edge 104 to data input/output terminals of memory devices associated with the first surface 110, bypassing the first buffer component 112 to minimize signal path delays for high-speed data transfers.

The second signal routing layer may be positioned within the PCB 102 structure and associated with the second surface 120 to provide electrical pathways for signals related to components mounted on the second surface 120. The second signal routing layer may include control signal input lines that carry control signals, address signals, and clock signals from specific electrical contacts 108 at the connector edge 104 to the control signal input of the second buffer component 114 mounted on the second surface 120. The second signal routing layer may include control signal output lines that carry buffered and registered control signals from the plurality of control signal outputs of the second buffer component 114 to respective memory devices in the second subset, including memory devices mounted on both the first surface 110 and second surface 120 that are served by the second buffer component 114. The second signal routing layer may include data signal lines that provide direct electrical pathways from data-related electrical contacts 108 at the connector edge 104 to data input/output terminals of memory devices associated with the second surface 120.

This dual routing layer configuration may enable efficient signal distribution while minimizing PCB complexity and layer count requirements. The separation of control signal input lines, control signal output lines, and data signal lines within each routing layer may prevent signal interference and crosstalk between different signal types that operate at different frequencies and timing requirements. The association of each routing layer with a respective surface may allow the control signal input lines to route from the electrical contacts 108 to buffer components along one side of the memory devices, while the control signal output lines route from the buffer components back to the memory devices along the opposite side, and the data signal lines route directly from the electrical contacts 108 to memory devices through the most direct available paths. This routing arrangement may enable all three signal types to utilize the same physical routing layer without interference, significantly reducing the total number of PCB layers compared to conventional memory module designs where different signal types require dedicated routing layers.

In some examples, the PCB 102 may comprise only one routing layer per surface, with the first signal routing layer being the single routing layer associated with the first surface 110 and the second signal routing layer being the single routing layer associated with the second surface 120. This single routing layer per surface configuration may enable all signal types including control signal input lines, control signal output lines, and data signal lines to coexist on the same conductive layer without interference due to the optimized spatial arrangement of buffer components and memory devices. The single routing layer approach may significantly reduce PCB manufacturing complexity and costs while maintaining the electrical performance required for high-speed memory operations by eliminating the need for multiple dedicated signal routing layers that would otherwise be required to separate different signal types.

In some examples, the PCB 102 may comprise altogether ten conductive layers or eight or 7 or 6 conductive layers or fewer conductive layers total, representing a substantial reduction from conventional memory module designs that may require fourteen or more conductive layers. The reduced total layer count may include the first and second signal routing layers along with additional essential conductive layers required for memory module functionality. The additional conductive layers may include power supply planes that distribute supply voltages such as core voltage, input/output voltage, and reference voltage to memory devices and buffer components throughout the PCB 102. The additional conductive layers may include ground planes that provide reference potentials for signal integrity and electromagnetic shielding to minimize interference between high-frequency signals. The reduced layer count PCB 102 may further include specialized conductive layers such as clock distribution layers that carry high-frequency clock signals with controlled impedance characteristics to ensure proper timing relationships between memory devices and buffer components. The PCB 102 may include power management layers that handle power sequencing signals, voltage regulation control signals, and power-on reset signals required for proper memory module initialization and operation. The PCB 102 may include thermal management layers or heat spreading layers that aid in heat dissipation from high-power components such as memory devices and buffer components, and may include electromagnetic interference shielding layers that isolate sensitive signals from external interference sources while maintaining signal integrity performance throughout the memory module 100.

The above described memory module 100 may enable significant cost reduction and manufacturing efficiency improvements compared to conventional memory module designs through the optimized component placement and routing architecture. The memory module 100 may provide reduced PCB layer count requirements by enabling control signal input lines, control signal output lines, and data signal lines to utilize the same routing layers without interference, potentially reducing total conductive layers from fourteen layers to eight or ten layers. The memory module 100 may enable improved signal integrity performance by minimizing routing distances for high-speed data signals through the placement of memory devices adjacent to the connector edge 104, while simultaneously optimizing control signal distribution through the strategic positioning of buffer components at the opposite edge 106. The memory module 100 may provide enhanced electrical loading distribution by enabling each buffer component to serve memory devices on both the first surface 110 and second surface 120 through cross-surface electrical coupling.

The memory module 100 may enable higher memory density and improved system scalability by supporting multiple memory devices on both surfaces of the PCB 102 while maintaining signal integrity through registered clock driver functionality and optimized routing paths. The memory module 100 may provide reduced electromagnetic interference and crosstalk through the spatial separation of different signal types and the use of dedicated routing layers associated with each surface. The memory module 100 may enable simplified PCB manufacturing processes and reduced production costs through the elimination of multiple dedicated signal routing layers that would otherwise be required to maintain signal isolation between different functional blocks. The memory module 100 may provide enhanced thermal management characteristics by distributing heat-generating components across different areas of the PCB 102 and may enable improved system reliability through the incorporation of registered clock driver components that buffer and condition control signals for stable high-speed memory operation.

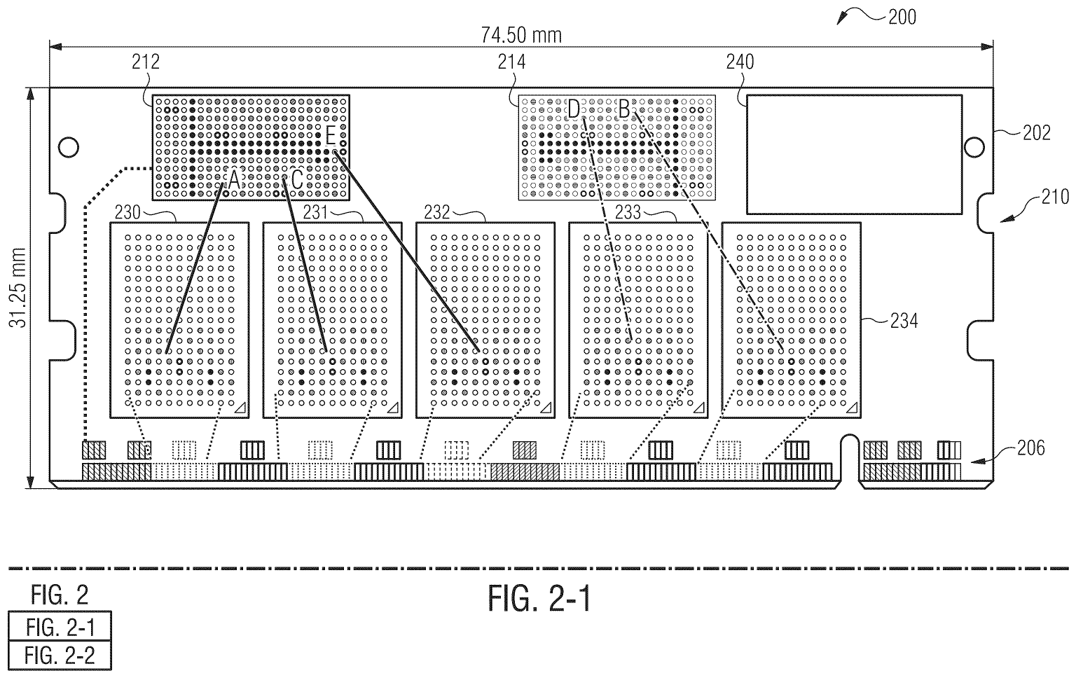

Further, the memory module may comprise further components not shown in FIG. 1 (see for example FIGS. 2-4 below) as described next. It should be understood that not all possible elements of the memory module 100 described next need to be present simultaneously in any particular embodiment. Various combinations and sub-combinations of the described elements may be implemented depending on the specific requirements and design considerations of the memory module 100.

In some examples, the memory module 100 may further comprise a power management integrated circuit (PMIC) mounted on the first surface 120 or the second surface 130 of the PCB 102. For example, PMIC may be a specialized integrated circuit that regulates and distributes electrical power to various components on the memory module 100 to ensure stable and efficient operation. The PMIC may receive input power from the host system through dedicated power supply electrical contacts 108 on the connector edge 104 and convert these voltages to the specific voltage levels required by different components such as memory devices, buffer components, and other support circuits. The PMIC may include voltage regulators, power sequencing circuits, and power monitoring functions that ensure proper startup sequences, maintain voltage stability under varying load conditions, and provide protection against overcurrent, overvoltage, and thermal conditions. The PMIC may enable the memory module 100 to operate with improved power efficiency and may provide enhanced power management capabilities compared to simpler power distribution approaches.

The PMIC may be mounted on either the first surface 110 or the second surface 120 of the PCB 102 depending on routing optimization, thermal management requirements, and available space constraints. In some examples, the PMIC may be positioned near the buffer components to minimize routing distances for control signals and power distribution lines that coordinate power management functions with memory operations. The PMIC may be located adjacent to high-power memory devices to provide localized voltage regulation and reduce power supply noise that could affect memory performance. The PMIC may include multiple voltage output channels that provide core supply voltages for memory device operation, input/output supply voltages for interface circuits, and reference voltages for analog circuits within the buffer components. The PMIC may incorporate power sequencing logic that coordinates the startup and shutdown sequences of different voltage domains to prevent latch-up conditions and ensure reliable memory module initialization during system power-on events.

In some examples, the memory module 100 may be configured for installation in a memory socket on a system board dimensioned to fit within a 19-inch equipment rack form factor. For example, the 19-inch equipment rack may be a standardized mounting framework used in data centers, server rooms, and telecommunications facilities to house electronic equipment in a compact and organized manner. The 19-inch equipment rack may have a standardized mounting width of 19 inches (approximately 482.6 millimeters) between the vertical mounting rails, providing a universal form factor that enables interchangeable installation of various electronic components and systems. The 19-inch equipment rack may include multiple rack units (U) of vertical space, with each rack unit measuring 1.75 inches (44.45 millimeters) in height, allowing system boards and servers to be stacked vertically within the rack structure. The 19-inch equipment rack may provide mechanical support, cooling airflow management, and cable management infrastructure that enables high-density installation of computing equipment in professional environments.

The memory module 100 may be configured for installation in a memory socket on a system board that is dimensioned to fit within the 19-inch equipment rack form factor, creating a cascaded mounting relationship where the memory module 100 connects to the system board, and the system board mounts within the rack structure. The system board may be a motherboard, server board, or computing platform that includes multiple memory sockets designed to accept memory modules and provide electrical connections to system processors and other components. The memory socket may be a connector assembly mounted on the system board that receives the connector edge 104 of the memory module 100 and establishes electrical contact between the electrical contacts 108 and the system board circuitry. The system board may be designed with specific dimensional constraints to fit within the 19-inch rack width, which may limit the available space for memory sockets and influence the maximum length and width dimensions that memory modules can have while still allowing proper installation and removal within the confined rack space.

The memory module 100 may be specifically configured with dimensional and mechanical characteristics that enable successful installation in memory sockets on system boards operating within the space constraints of 19-inch equipment racks. The memory module 100 may have a reduced module length or modified form factor that allows multiple memory modules to be installed on a single system board without exceeding the 19-inch rack width limitations. The memory module 100 may include mechanical features such as retention clips, insertion guides, or clearance allowances that facilitate installation and removal within the confined space available in rack-mounted systems where adjacent equipment and cable routing may restrict access to memory sockets.

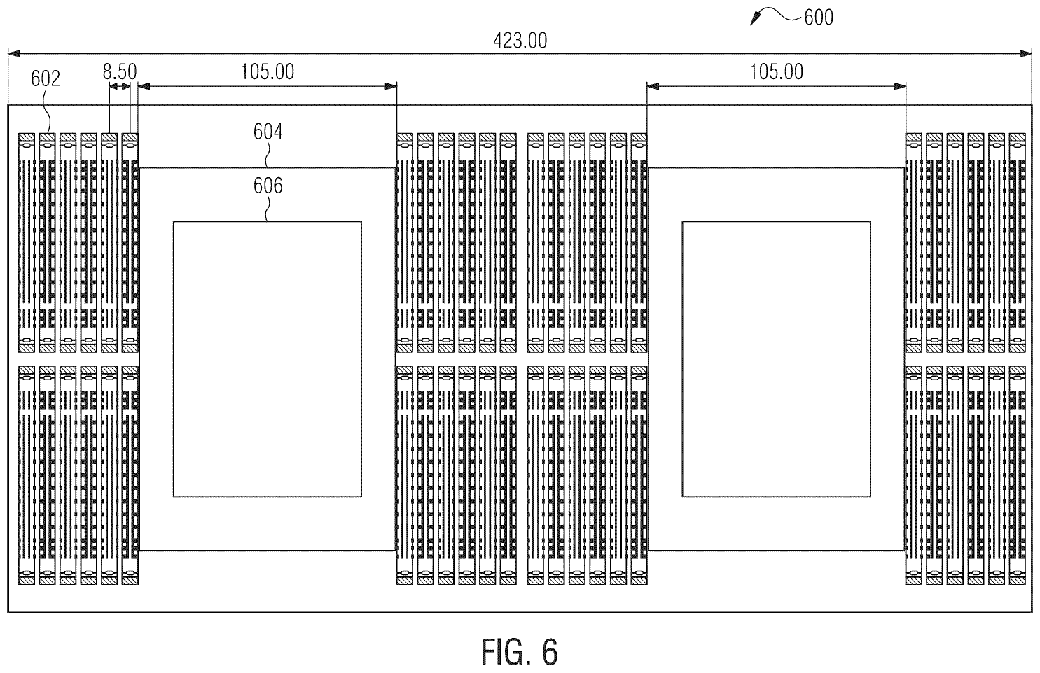

In some examples, the memory module 100 and/or the PCB may have a module length of 80 millimeters or less. For example, the memory module 100 and/or the PCB may have a module length of 74.50 millimeters or less. For example, the memory module 100 and the PCB 102 may have a module length of 80 millimeters or less, representing a significant reduction compared to standard memory module dimensions used in conventional server and workstation applications. Standard DIMMs and RDIMMs may typically have module lengths of approximately 133 millimeters (see also FIG. 7 below) for full-size server memory modules, which corresponds to established industry form factors that have been widely adopted across server platforms. The reduced module length of 80 millimeters or less may represent approximately a 40% reduction in the length dimension compared to these standard memory module form factors, enabling more compact memory module designs that can fit within space-constrained applications and system configurations.

The reduced module length of 80 millimeters or less may enable the memory module 100 to be installed in memory sockets on system boards that must fit within the dimensional constraints of 19-inch equipment racks while accommodating other system components and maintaining proper clearances for airflow and serviceability. The shorter module length may allow system board designers to position memory sockets closer together or to allocate more board space for other critical components such as processors, expansion slots, or cooling systems. The 80-millimeter or less module length may enable improved memory density per unit of rack space by allowing more memory modules to be installed within the same system board area, or may enable the design of narrower system boards that can accommodate additional parallel systems within the same 19-inch rack width. The reduced module length may also facilitate improved thermal management by reducing the overall thermal footprint of each memory module and enabling better airflow distribution around memory components within rack-mounted systems.

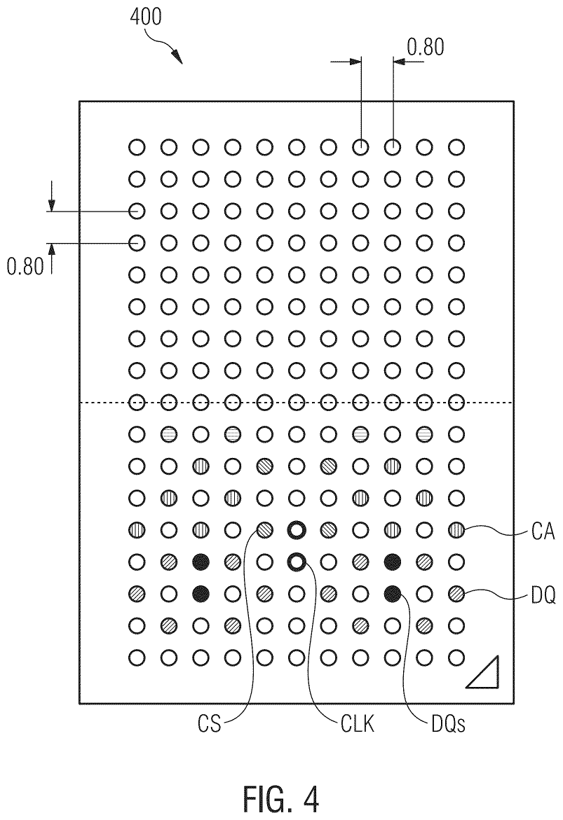

In some examples, the memory module and/or the PCB may have a module length of less than 80 millimeters, thereby enabling two such memory modules to be installed in vertically adjacent memory sockets within the width constraints of a standard 19-inch equipment rack form factor. This reduced module length may be achieved through the optimized component placement described previously, where memory devices are positioned adjacent to the connector edge 104 and buffer components are positioned at the opposite edge 106, along with the efficient routing architecture that reduces PCB layer count and enables more compact PCB designs. The module length of less than 80 millimeters may enable two such memory modules to be installed in vertically adjacent memory sockets within the width constraints of a standard 19-inch equipment rack form factor, effectively doubling the memory module density compared to conventional memory module installations. The vertically adjacent installation may involve positioning memory sockets on the system board such that two memory modules can be mounted side-by-side across the width of the system board, with both modules fitting within the 19-inch rack mounting width constraint (see also FIG. 5 below). This configuration may achieve higher memory capacity per rack unit by installing twice as many memory modules on each system board compared to systems using standard-length memory modules. The ability to install two memory modules in vertically adjacent sockets may provide significant advantages for high-density computing applications such as server consolidation, cloud computing platforms, and data center environments where maximizing memory capacity per unit of rack space directly impacts system performance, power efficiency, and total cost of ownership.

In some examples, the PCB 102 has a reduced module width relative to a standard RDIMM form factor, enabling placement of two memory modules side by side within the width of a conventional dual-slot server system. A conventional dual-slot server system may normally accommodate only a single standard-width memory module. The reduced memory module 100 width may be achieved through the compact component arrangement and optimized routing architecture as described above that eliminates the need for additional PCB area typically required for conventional memory module designs with less efficient signal routing and component placement. This reduced width configuration may enable server system designers to install twice as many memory modules within the same physical space constraints of existing server platforms, effectively doubling the memory capacity or memory channel count without requiring modifications to server chassis dimensions or cooling infrastructure. The ability to place two memory modules 100 side by side within a conventional dual-slot server system width may provide significant advantages for memory-intensive applications by increasing memory bandwidth through additional parallel memory channels and may enable cost-effective server upgrades that maximize memory performance within existing system form factors.

In some examples, the memory devices may be positioned such that a shortest routing distance from the connector edge to a data terminal of a memory device is no greater than 20 millimeters. This may ensure minimal signal path lengths for high-speed data transmission between the electrical contacts 108 and the memory device data input/output terminals. This 20-millimeter maximum routing distance constraint may be achieved through the strategic placement of memory devices adjacent to the connector edge 104, which positions the data terminals of the memory devices in close proximity to the corresponding data signal electrical contacts 108 on the connector edge 104. The shortest routing distance limitation may significantly improve signal integrity performance by reducing transmission line effects, signal attenuation, and electromagnetic interference that typically increase with longer routing paths, particularly at the high data rates associated with DDR6 memory protocols that may operate at frequencies exceeding several gigahertz. The 20-millimeter constraint may enable the memory module 100 to maintain signal timing precision and reduce signal skew between different memory devices, which is critical for maintaining synchronous operation across multiple memory devices operating in parallel data channels. This routing distance optimization may also reduce power consumption by minimizing the drive strength requirements for data signals and may improve signal-to-noise ratios by reducing the opportunity for noise coupling along extended routing paths.

In some examples, the set of electrical contacts on the connector edge may comprise at least 120 data signal contacts or more. This may provide parallel data pathways for high-bandwidth data transfer between the memory module 100 and the host system memory controller. The 120 data signal contacts may represent a significant increase in data width compared to conventional memory modules that may provide 64, 72, or fewer parallel data contacts, enabling the memory module 100 to achieve higher data throughput rates by transferring more data bits simultaneously during each clock cycle. The 120 data signal contacts may be organized into multiple data groups or data channels that can operate independently or in coordination to support various memory access patterns and data transfer modes required by different processor architectures and system configurations. The increased number of data signal contacts may enable the memory module 100 to support wider memory interfaces that can improve system performance for memory-intensive applications such as high-performance computing, artificial intelligence processing, and large-scale data analytics where memory bandwidth often becomes a performance bottleneck. The 120 data signal contacts may be implemented alongside additional electrical contacts 108 for control signals, address signals, clock signals, and power supply connections, requiring careful contact arrangement and spacing to maintain signal integrity while accommodating the increased contact density within the connector edge 104 form factor constraints.

In some example, the set of electrical contacts on the connector edge comprises a contact pitch configured to provide at least 3 electrical contacts per millimeter of edge length. This may enable high-density contact arrangements that support the increased number of data signal contacts and control signal contacts required for advanced memory module functionality. The contact pitch of at least 3 contacts per millimeter may represent a significantly finer pitch compared to conventional memory module contact arrangements that may provide 2 contacts per millimeter or lower contact densities, requiring advanced manufacturing techniques and precision tooling to achieve reliable electrical connections within the reduced contact spacing. This high-density contact pitch may be achieved through miniaturized contact geometries, optimized contact materials, and advanced plating processes that maintain electrical performance while accommodating the reduced physical dimensions of individual contacts. The fine contact pitch may enable the memory module 100 to provide the 120 data signal contacts along with additional control and power contacts within the standard connector edge 104 length constraints, eliminating the need for longer connector edges that would increase the overall memory module dimensions. The 3 contacts per millimeter pitch may require corresponding precision in the memory socket design and manufacturing to ensure proper alignment and reliable electrical contact between the memory module contacts and the socket contacts throughout the operational temperature range and mechanical stress conditions encountered in server and workstation environments.

In some examples, the memory device package may comprise data terminals located along a first edge of the memory device package and control terminals located adjacent to the data terminals. This may create an optimized terminal arrangement that facilitates efficient routing between the memory devices and other components on the memory module 100. The data terminals may include input/output pins or ball grid array contacts that carry bidirectional data signals between the memory device and the PCB 102 routing layers, enabling high-speed data transfer during read and write operations. The control terminals may include pins or contacts that receive control signals such as row address strobe signals, column address strobe signals, write enable signals, chip select signals, and clock signals that coordinate memory device operations and timing. The adjacent positioning of data terminals and control terminals along the first edge of the memory device package may enable both signal types to be routed using similar routing paths and may reduce the PCB area required for memory device connections. This terminal arrangement may also facilitate the optimized routing architecture where data signal lines can route directly from the electrical contacts 108 to the memory device data terminals while control signal output lines from buffer components can route to the adjacent control terminals using parallel routing paths that minimize interference and crosstalk between different signal types.

In some examples, buffer component may comprise one or more control signal input ports and five or more or less control signal output ports. This setup may provide a signal distribution architecture that enables each buffer component to serve multiple memory devices with dedicated control signal paths. For example, a single control signal input port may receive combined control signals, address signals, and clock signals from the electrical contacts 108 on the connector edge 104, providing a consolidated input interface that simplifies routing from the connector edge 104 to the buffer component location. For example, five control signal output ports may provide independent buffered and registered control signals to five respective memory devices, enabling each buffer component to manage exactly five memory devices with dedicated signal paths that minimize electrical loading and signal interference between different memory devices. For example, a one-to-five signal distribution ratio may correspond to the memory device arrangement where five memory devices are mounted on each surface of the PCB 102, allowing the first buffer component 112 to serve five memory devices and the second buffer component 114 to serve the remaining five memory devices through their respective five control signal output ports. The five control signal output ports may enable each buffer component to provide individualized timing control and signal conditioning for each connected memory device, optimizing signal integrity and enabling fine-tuned timing adjustments that may be required for high-speed memory operation across multiple memory devices operating in parallel.

Further details and aspects are mentioned in connection with the examples described below. The example shown in FIG. 1 may include one or more optional additional features corresponding to one or more aspects mentioned in connection with the proposed concept or one or more examples described below (e.g., FIGS. 2-12).

FIG. 2 illustrates a second example of a memory module 200. For example, the components mentioned in the memory module 200 may be defined and characterized as described above with regard to FIG. 1, including the PCB, electrical contacts, memory devices, buffer components, control signal input and output lines, data signal lines, and/or signal routing layers.

The memory module 200 comprises a PCB 202 with overall dimensions of 74.50 mm length and 31.25 mm width. This reduced form factor may enable 120 data query (DQ) signals per dual inline memory module (DIMM) to increase 50% input/output (I/O) width while reducing the DIMM length to allow placement of two DIMMs side by side within conventional server system constraints. The memory module 200 shows both the first surface 210 (top view) and second surface 220 (bottom view) to illustrate the dual-surface component mounting arrangement and cross-surface electrical coupling between buffer components and memory devices.

The memory module 200 comprises five dynamic random access memory (DRAM) devices 230, 231, 232, 233, 234 mounted on the first surface 210, positioned adjacent to the connector edge which includes the electrical contacts 206 (gold fingers) for system connection. The memory module 200 further comprises five DRAM devices 235, 236, 237, 238, 239 mounted on the second surface 220, also positioned adjacent to the connector edge to minimize routing distances for data query (DQ) signals traveling directly from the DIMM connector gold fingers 206 to DRAM ball grid array (BGA) contacts for improved signal integrity (SI) performance. The DRAM devices are arranged in a linear configuration running parallel to the connector edge 206, with each memory device package utilizing ×12 DRAM packages where data query (DQ) terminals are placed at the edge and command/address (CA) terminals are located adjacent to the DQ terminals to facilitate efficient routing optimization and reduce wirebond length compared to ×24 DRAM packages.

The memory module 200 includes a registered clock driver (RCD) buffer 212 component om the first surface and a RCD buffer component 214 on the second surface 214 positioned at the edge opposite to the connector edge 206. The RCD 212 is mounted on the primary side and electrically coupled to memory devices 230, 231, 232 on the first surface 210 and memory devices 235, 236 on the second surface through cross-surface routing connections. The RCD 214 is mounted on the secondary side 220 and electrically coupled to memory devices 233, 234 on the first surface and memory devices 237, 238, 239 on the second surface. Each RCD comprises one device command/address (DCA) input port that receives control signals from the connector edge 206 and five qualified command/address (QCA) output ports that provide dedicated buffered control signals to respective DRAM devices, with each QCA port connecting to only one DRAM CA port for better signal integrity.

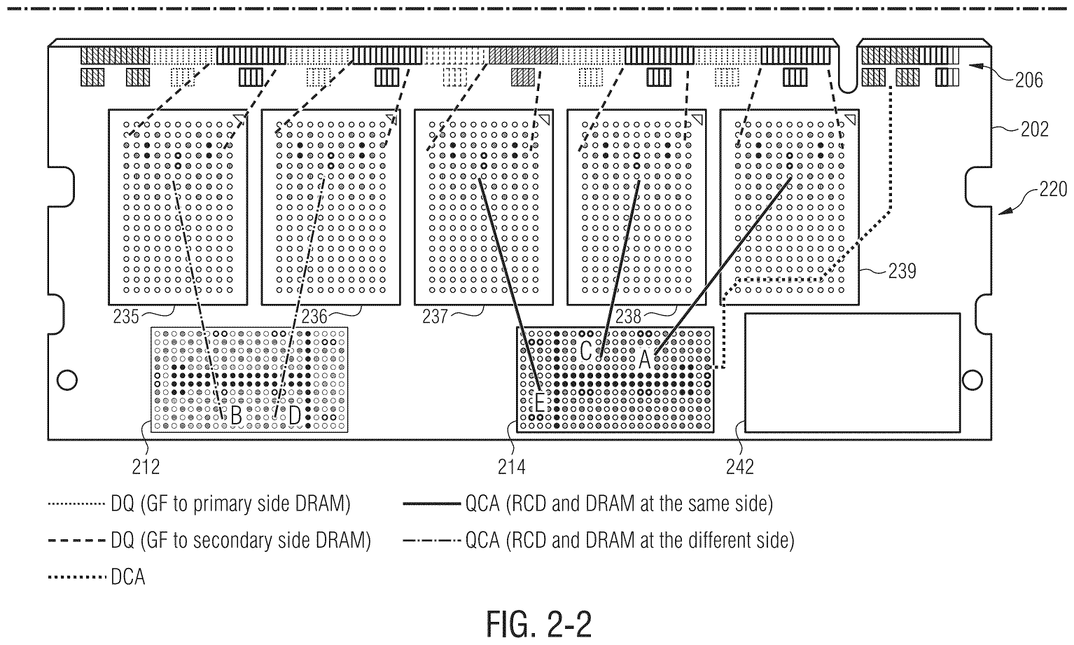

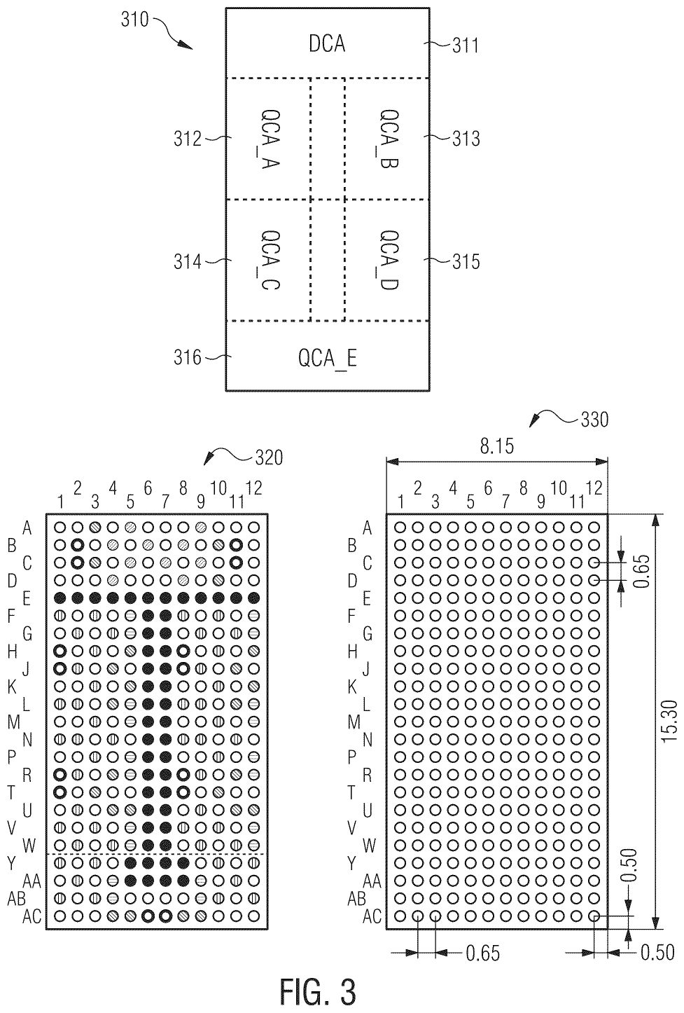

The memory module 200 further comprises one or two power management integrated circuits (PMIC) 240/242 mounted on the first surface 210 and/or on the second surface 220. The PMIC 240/242 may be positioned near the RCD components to provide localized power regulation and distribution for the memory devices and buffer components. The routing patterns is indicating different signal types including DQ signal lines that route directly from the connector edge 206 to the DRAM data terminals, DCA signal input lines that route from the gold fingers 206 to the RCD DCA ports through areas close to the edge, and QCA signal output lines that route from the RCD components to the DRAM devices. The routing visualization demonstrates how the DCA, QCA, and DQ signals can coexist on single routing layers associated with each surface without interference due to the strategic placement of gold fingers and RCDs on different sides of the DRAM devices, enabling significant reduction in RDIMM layer count from for example conventional 14-layer DDR5 RDIMM designs to for example 8 or 10 layers for DDR6 RDIMM while maintaining signal integrity performance required for high-speed DDR6 memory operation (see also FIGS. 3 and 4).

The disclosed optimized RDIMM form factor and component placement enables more memory channels within the same system form factor, provides RDIMM routing with reduced DQ length from the DIMM connector gold finger to DRAM die for better signal integrity performance, and allows DCA, QCA and DQ signals to be routed on the same layer to reduce RDIMM layer count for cost reduction. The DRAM die connections utilize single side wirebond to the DRAM substrate to reduce DIMM routing length from gold finger to BGA ball, and the x12 DRAM package configuration with less die stacking reduces wirebond length compared to ×24 DRAM packages for improved signal integrity characteristics.

Further details and aspects are mentioned in connection with the examples described above or below. The example shown in FIG. 2 may include one or more optional additional features corresponding to one or more aspects mentioned in connection with the proposed concept or one or more examples described above (e.g., FIG. 1) or below (e.g., FIGS. 3-12).

FIG. 3 illustrates the layout of a registered clock driver (RCD) component. FIG. 3 shows the same RCD from three different perspectives: component 310 displays the logical port configuration, component 320 shows the physical ball grid array implementation, and component 330 presents the dimensional specifications, with all three views representing the same RCD component. The RCD component demonstrates the specific port configuration and physical layout that enables the optimized signal distribution architecture described in the memory module designs above.

The logical view 310 shows the RCD component comprising a device command/address (DCA) input port 311 that receives control signals, address signals, and clock signals from the connector edge electrical contacts. The RCD component 310 includes five qualified command/address (QCA) output ports designated as QCA_A 312, QCA_B 313, QCA_C 314, QCA_D 315, and QCA_E 316, providing dedicated signal distribution to respective memory devices. Each QCA output port connects to only one DRAM command/address (CA) port for improved signal integrity (SI) performance, eliminating signal loading and interference issues that could occur with shared control signal paths. This one-to-five signal distribution ratio corresponds directly to the five memory devices served by each RCD component in the memory module arrangements described above.

The physical implementation view 320 displays the same RCD component with a ball grid array (BGA) pattern showing a rectangular grid arrangement of solder ball contact points organized in numbered rows (1-12) and lettered columns (A-AC) across the package substrate. The grid coordinate system enables precise identification of each individual contact location, with specific positions designated for different signal types. The BGA pattern includes contact points positioned throughout the grid, with DCA input signals including address lines, control signals, and clock inputs located at specific coordinate positions within designated regions of the package. The QCA output contact points are distributed across different grid locations, with each of the five QCA output groups (QCA_A through QCA_E) having dedicated coordinate positions that correspond to the command and address signals routed to each respective memory device. The package substrate includes power supply and ground contact points positioned at strategic grid coordinates throughout the BGA pattern to provide supply voltage distribution and ground reference connections. The coordinate-based layout enables precise documentation and manufacturing control, ensuring that each logical signal from the DCA input port and five QCA output ports maps to specific grid positions that enable reliable electrical connection to the PCB routing layers when the RCD component is mounted using surface-mount technology reflow soldering processes.

The dimensional specification view 330 shows the same RCD component with precise measurements that define the overall package footprint and contact spacing requirements for PCB mounting and electrical connection. The component has an overall package dimension of 8.15 mm width and 15.30 mm length, establishing the rectangular area that must be allocated on the PCB surface for component placement and the clearance zones required around the component for assembly and thermal management. The detailed pin spacing specifications include a 0.50 mm pitch measurement in one direction and a 0.65 mm pitch measurement in the perpendicular direction, indicating that the solder ball contacts are arranged in a non-square grid pattern with different spacing between rows and columns. The 0.50 mm pitch represents the center-to-center distance between adjacent contact points along one axis of the BGA grid, while the 0.65 mm pitch represents the center-to-center spacing along the perpendicular axis, creating a rectangular contact pattern rather than a square grid arrangement. These precise pitch measurements are critical for PCB pad design, as the PCB must have corresponding contact pads positioned at exactly the same spacing to ensure proper electrical connection when the RCD component is placed and soldered using surface-mount technology processes. The dimensional specifications also include tolerance requirements and keepout zones that define the minimum spacing required between the RCD component and adjacent components on the PCB surface to prevent mechanical interference during assembly and to maintain proper electrical isolation between different circuit elements. The standardized dimensions enable the same RCD component to be used consistently across different memory module designs while ensuring reliable mounting and electrical performance on various PCB configurations.

All three representations demonstrate how the single RCD component design maintains identical electrical connections, physical dimensions, and mounting characteristics while showing different aspects necessary for comprehensive understanding of both functional and physical implementation requirements. The RCD form factor and floorplan shown enable each buffer component to provide dedicated control signal buffering and distribution to exactly five memory devices through the five QCA output ports, supporting the memory device arrangements where five DRAMs are placed on each surface of the DDR6 RDIMM. The single DCA input port architecture simplifies routing from the connector edge to the RCD components while the five dedicated QCA output ports ensure optimal signal integrity by providing individual control signal paths to each connected memory device without electrical loading interactions between different memory devices.

Further details and aspects are mentioned in connection with the examples described above or below. The example shown in FIG. 3 may include one or more optional additional features corresponding to one or more aspects mentioned in connection with the proposed concept or one or more examples described above (e.g., FIGS. 1 to 2) or below (e.g., FIGS. 4-12).

FIG. 4 illustrates a memory device 400. The memory device 400 may be a ×12 DDR6 DRAM floorplan and package implementation used in the memory modules described above. The memory device 400 demonstrates the optimized terminal arrangement that enables reduced routing distances and improved signal integrity (SI) performance compared to conventional ×24 DRAM packages. The figure shows the ball grid array (BGA) contact pattern from the substrate side, with contact points arranged in a rectangular grid pattern with specific spacing dimensions of 0.80 mm pitch in both directions.

The memory device 400 utilizes an x12 DRAM package configuration where data query (DQ) terminals are strategically placed at the edge of the package and command/address (CA) terminals are positioned adjacent to the DQ terminals. The BGA contact pattern shows different signal groups distributed across the package footprint, with chip select (CS) contacts positioned in one region, clock (CLK) contacts in another region, data query (DQs) contacts along the edges, and command/address (CA) contacts adjacent to the data contacts. The contact arrangement demonstrates how the DQ signals are placed at the package edge to minimize routing distance from the DIMM connector gold fingers to the BGA ball contacts, reducing signal path lengths for high-speed data transmission. The CA terminals positioned next to the DQ terminals enable efficient routing of both signal types using similar paths on the PCB routing layers.

The ×12 DRAM package design incorporates reduced die stacking compared to ×24 DRAM packages, with the DRAM die connected to the DRAM substrate using single-side wirebond connections. The reduced die stacking configuration minimizes wirebond length between the silicon die and the package substrate, providing improved signal integrity characteristics by reducing parasitic inductance and capacitance associated with longer wirebond connections. The single-side wirebond approach enables more direct electrical connections between the memory cells on the DRAM die and the external BGA contacts, reducing signal distortion and timing variations that could affect high-speed DDR6 memory operation. The optimized package design supports the overall memory module architecture by reducing the DIMM routing length from gold finger to BGA ball, contributing to the improved signal integrity performance and enabling the higher data rates required for DDR6 memory protocols.

The DRAM floorplan shown enables the memory devices to integrate effectively with the routing architectures described in the previous figures, where the edge placement of DQ terminals facilitates direct routing from connector edge contacts to memory device data terminals while the adjacent CA terminal placement enables efficient routing from RCD QCA outputs to memory device control inputs. The ×12 package configuration with reduced die stacking and optimized terminal placement contributes to the overall system performance improvements achieved through the coordinated design of memory module form factor, component placement, and routing optimization.

Further details and aspects are mentioned in connection with the examples described above or below. The example shown in FIG. 4 may include one or more optional additional features corresponding to one or more aspects mentioned in connection with the proposed concept or one or more examples described above (e.g., FIGS. 1-3) or below (e.g., FIGS. 5-12).

FIG. 5 illustrates a cross-sectional view of a memory device 500. The memory device 500 shows a ×12 DDR6 DRAM die stacking configuration that enables reduced wirebond lengths and improved signal integrity compared to conventional ×24 DRAM packages. The memory device 500 demonstrates the vertical stacking arrangement of memory dies within the package and the single-side wirebond connection methodology that optimizes electrical performance for high-speed DDR6 memory operation.

The memory device 500 comprises a package substrate 512 that provides the foundation for die mounting and electrical connections to the external ball grid array contacts. The die stack includes multiple memory dies with die R0 514, die R1 516, and die 2DS 518 representing different memory dies stacked vertically within the package. Die layer 520 represents the top die in the stack configuration. The cross-sectional view shows how the individual DRAM dies are positioned in a stacked arrangement to maximize memory capacity within the package footprint while maintaining controlled thickness dimensions for the overall package height.

The ×12 DRAM package utilizes single-side wirebond connections between the DRAM dies and the package substrate 512, as shown by the wirebond connections extending from the edge of each die to bonding pads on the substrate. The single-side wirebond approach enables shorter electrical connection paths compared to double-side or more complex wirebond configurations, reducing parasitic inductance and capacitance that could degrade signal integrity at high operating frequencies. The reduced die stacking in the x12 configuration minimizes the total wirebond length required to connect all memory dies to the substrate, providing better signal integrity characteristics compared to ×24 DRAM packages that require more extensive die stacking and longer wirebond connections.

The die stacking configuration shown enables the memory device 500 to reduce the DIMM routing length from gold finger to BGA ball by positioning the data query (DQ) terminals at the package edge and command/address (CA) terminals adjacent to the DQ terminals, as described in the previous figure. The optimized die stacking with reduced wirebond lengths contributes to improved signal integrity performance by minimizing signal distortion and timing variations within the package, supporting the higher data rates and stricter timing requirements associated with DDR6 memory protocols. The ×12 DRAM package design integrates with the overall memory module architecture to enable the routing optimizations and layer count reductions described in the memory module configurations above.

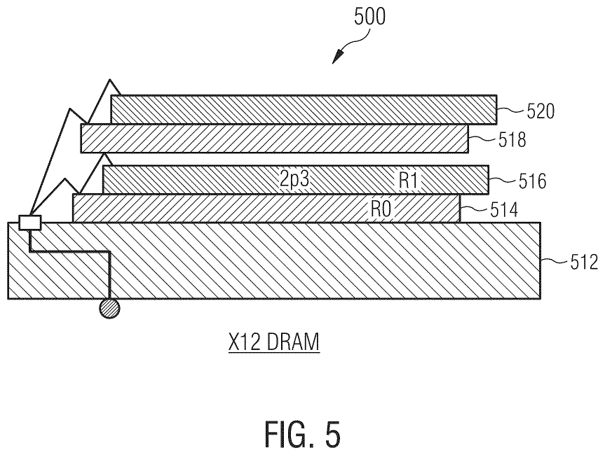

Further details and aspects are mentioned in connection with the examples described above or below. The example shown in FIG. 5 may include one or more optional additional features corresponding to one or more aspects mentioned in connection with the proposed concept or one or more examples described above (e.g., FIGS. 1-4) or below (e.g., FIGS. 6-12).

FIG. 6 illustrates a system board 600 comprising a plurality of memory sockets. The system board 600 comprises a DDR6 2-socket system configuration designed to fit within a 19-inch equipment rack form factor. This may demonstrate how the reduced memory module dimensions enable increased memory density and improved system performance within standard rack constraints. The system board 600 shows the overall dimensions of 423.00 mm length and incorporates multiple memory socket areas with precise spacing measurements including 108.00 mm between socket groups and 105.00 mm for individual socket sections, with 8.50 mm spacing between adjacent memory modules.

The system board 600 comprises a plurality of memory socket locations 602 arranged in groups along the board length, with each socket location configured to accept the reduced-length memory modules described in the previous figures. The memory socket arrangement shows how the 120 data query (DQ) signals per DIMM enable increased input/output (I/O) width by 50% compared to conventional memory configurations, supporting higher memory bandwidth within the same system form factor. The socket spacing 604 demonstrates the precise positioning required to accommodate the reduced DIMM length that allows placement of two DIMMs side by side within the width constraints of standard server systems.

The system board 600 includes designated areas 606 that represent the physical space allocation for each memory module, showing how the mini-DIMM design with reduced module length enables more efficient utilization of the available board area within the 19-inch rack mounting width constraints. The socket configuration enables the DDR6 2-socket system to support increased memory channel count and memory capacity compared to systems using conventional full-length memory modules. The precise dimensional specifications shown enable system designers to maximize memory density while maintaining proper clearances for component mounting, thermal management, and serviceability requirements within rack-mounted server environments.

The RDIMM registered clock driver (RCD) and DRAM placement and floorplan optimizations described in the previous figures enable reduced routing lengths for DDR6 performance scaling and reduced layer count for cost-effective solutions, as demonstrated by the system-level implementation shown. The mini-DIMM design integrates effectively with the 2-socket system architecture to provide enhanced memory performance and capacity within the standard 19-inch equipment rack form factor, enabling improved server consolidation and data center efficiency through higher memory density per rack unit.

Further details and aspects are mentioned in connection with the examples described above or below. The example shown in FIG. 6 may include one or more optional additional features corresponding to one or more aspects mentioned in connection with the proposed concept or one or more examples described above (e.g., FIGS. 1-5) or below (e.g., FIGS. 7-12).

FIG. 7 illustrates a memory socket connection system 700. The memory socket connection system 700 may be an technology showing existing DDR5 connector technology. The system 700 shows an edge card connector methodology used in memory architectures.

The system 700 comprises a DDR5 connector 704 that functions as an edge card connector mounted on the motherboard 706. The DIMM memory module 702 is configured for insertion into the connector slot, where the DIMM gold finger electrical contacts establish electrical connection with spring-loaded connector pins 710 within the DDR5 connector 704 to ensure reliable electrical contact between the memory module and the system circuitry. The gold finger contacts 712 on the memory module edge provide the electrical interface points that mate with the corresponding connector pins when the DIMM is fully inserted into the connector slot.

The DDR5 connector 704 is attached to the motherboard 706 through surface-mount technology (SMT) pads 708 that provide mechanical mounting and electrical connection between the connector assembly and the motherboard routing layers. The SMT pads enable the connector to be soldered to the motherboard during the board assembly process, creating permanent electrical pathways between the connector pins and the motherboard traces that route to processors, controllers, and other system components. The connector mounting configuration shows the established approach used in current DDR5 systems where the connector assembly provides a removable interface for memory modules while maintaining reliable electrical performance.

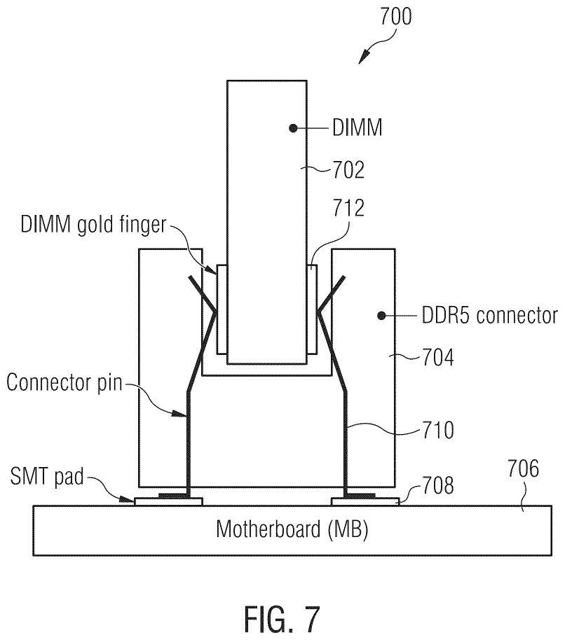

Further details and aspects are mentioned in connection with the examples described above or below. The example shown in FIG. 7 may include one or more optional additional features corresponding to one or more aspects mentioned in connection with the proposed concept or one or more examples described above (e.g., FIGS. 1-6) or below (e.g., FIGS. 8-12).

FIG. 8 illustrates a memory module 800. The memory module 800 may be an existing DDR5 connector and DIMM form factor technology that represents memory module dimensions and connector interface used in current server systems. The memory module 800 may be connected to the corresponding socket connector 802. The memory module 800 has standard DIMM dimensions including an overall length of 133.35 mm and width of 31.25 mm, representing the established form factor that has been widely adopted across server and workstation platforms. The memory module 800 shows individual DRAM devices positioned along the length of the module near the connector edge, with device dimensions of 11.00 mm and 10.00 mm defining the height and width specifications of each memory device package. The central region of the memory module 800 includes component placement areas for buffer circuits such as registered clock driver (RCD) and power management integrated circuit (PMIC) components, positioned in the middle area of the module between the memory devices arranged along the connector edge.

The socket connector 802 provides the mechanical housing and spring-loaded connector pins that establish electrical contact with the memory module's gold finger contacts when the DIMM is inserted into the connector slot. The socket connector 802 includes the interface mechanisms that mate with the electrical contacts on the memory module 800 to create the electrical pathways between the memory devices and the motherboard circuitry. The side profile view shows the system depth requirements with a 162.00 mm measurement indicating the total installation depth required for the complete memory module and socket assembly, including clearances for connector engagement, component heights, and proper mechanical fit within server chassis constraints.

The conventional DDR5 component arrangement shown places RCD and PMIC components in the central area of the memory module, which may require routing paths and additional PCB layers compared to the optimized placement described in the DDR6 RDIMM configurations where memory devices are positioned adjacent to the connector edge and buffer components are positioned at the opposite edge. The existing DDR5 form factor with its 133.35 mm length contrasts with the DDR6 that enable reduced module length of 80 millimeters or less, allowing two memory modules to be installed side by side within the width constraints of standard server systems.

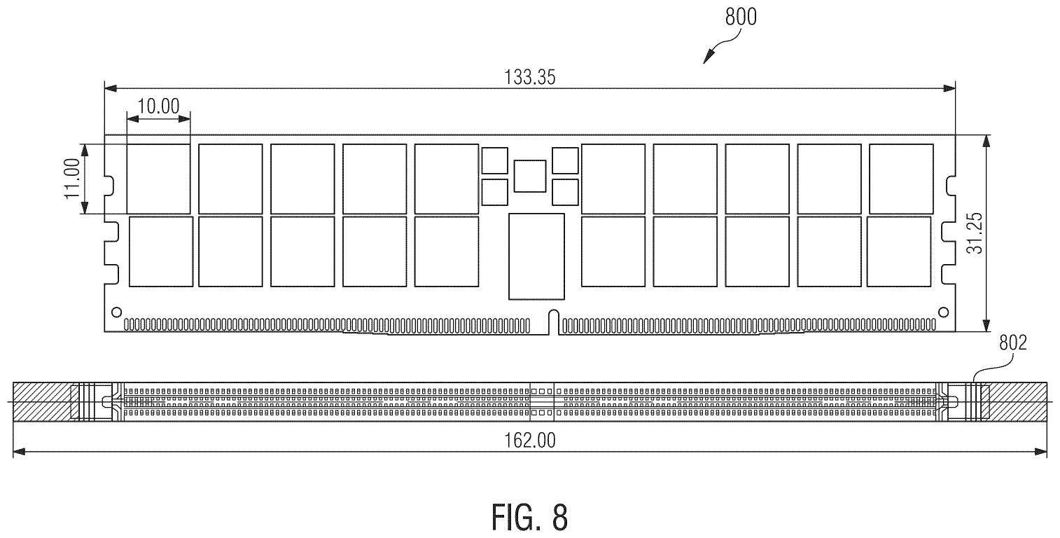

Further details and aspects are mentioned in connection with the examples described above or below. The example shown in FIG. 8 may include one or more optional additional features corresponding to one or more aspects mentioned in connection with the proposed concept or one or more examples described above (e.g., FIGS. 1-7) or below (e.g., FIGS. 9-12).

FIG. 9 illustrates a DDR5 system 900. The DDR5 system 900 shows a system-level implementation of DDR5 memory technology that represents an established system architecture used in server platforms. The system 900 comprises a full-size DDR5 connector arrangement with memory modules 902 positioned in standard socket configurations on the system board. The system includes routing paths shown by the arrows, with specific routing connections 908 and 910 indicating the signal pathways between different system components. The routing traces 908 show data signal paths while the routing connections 910 demonstrate control signal routing between the memory modules and system components such as processors 906 or memory controllers 904. The system architecture shows how conventional DDR5 systems handle signal distribution and routing within the established form factor constraints.

The system board layout includes central processing areas with multiple components such as the memory controller (MC) 904 and the processor package (PKG) 906 positioned in the middle region of the board, representing processors, chipsets, or other system logic that coordinates memory operations. The full-size DDR5 connector spacing and arrangement shows the established socket positioning that requires the standard 133.35 mm memory module length and conventional component placement approaches. The routing architecture demonstrates the signal path lengths and complexity associated with conventional DDR5 system implementations, which may require more extensive routing layers and longer signal paths compared to the optimized DDR6 configurations described above.

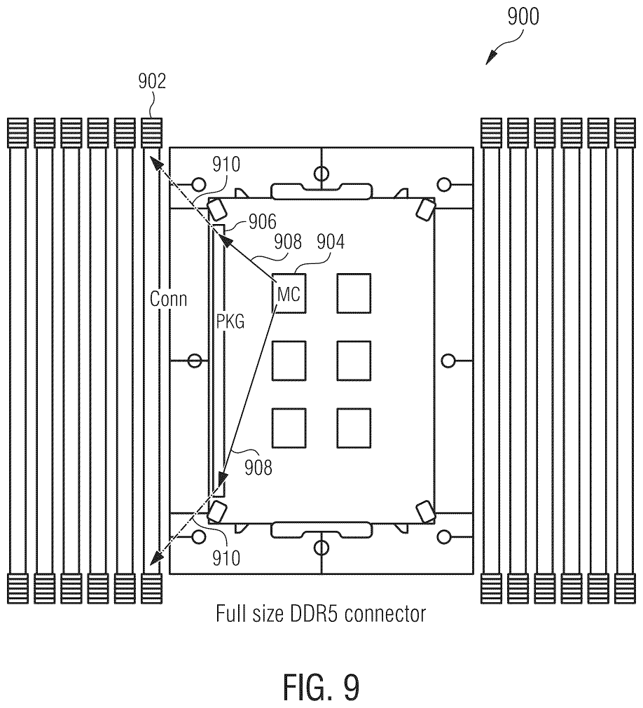

Further details and aspects are mentioned in connection with the examples described above or below. The example shown in FIG. 9 may include one or more optional additional features corresponding to one or more aspects mentioned in connection with the proposed concept or one or more examples described above (e.g., FIGS. 1-7) or below (e.g., FIGS. 10-12).

FIG. 10 illustrates a system board 1000. The system board comprises at least one memory socket 1002. The system board 1000 comprises further at least one memory module 100 as described with regards to FIG. 1 above, which is configured for installation into the memory socket 1002.

The PCB of the memory module 100 may have a module length of less than 80 millimeters, such as 74.50 mm thereby enabling two such memory modules to be installed in vertically adjacent memory sockets within the width constraints of a 19-inch equipment rack mounting width.

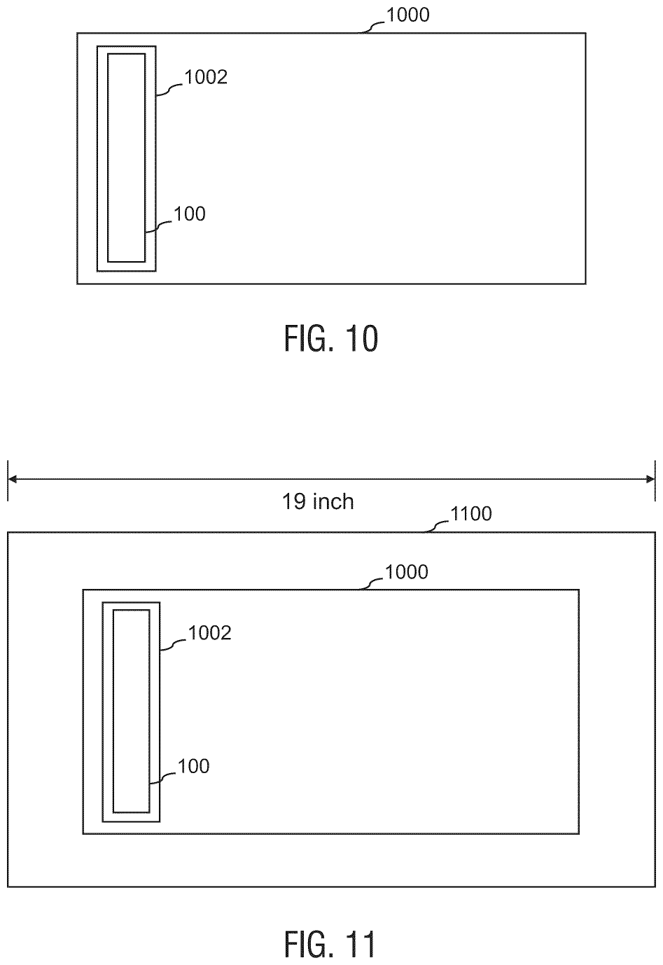

Further details and aspects are mentioned in connection with the examples described above or below. The example shown in FIG. 10 may include one or more optional additional features corresponding to one or more aspects mentioned in connection with the proposed concept or one or more examples described above (e.g., FIGS. 1-12) or below (e.g., FIG. 11).

FIG. 11 illustrates an equipment rack 1100. The equipment rack 1100 has a 19 inch mounting width. The equipment rack 1100 comprises the system board 1000 as described above with regards to FIG. 100.

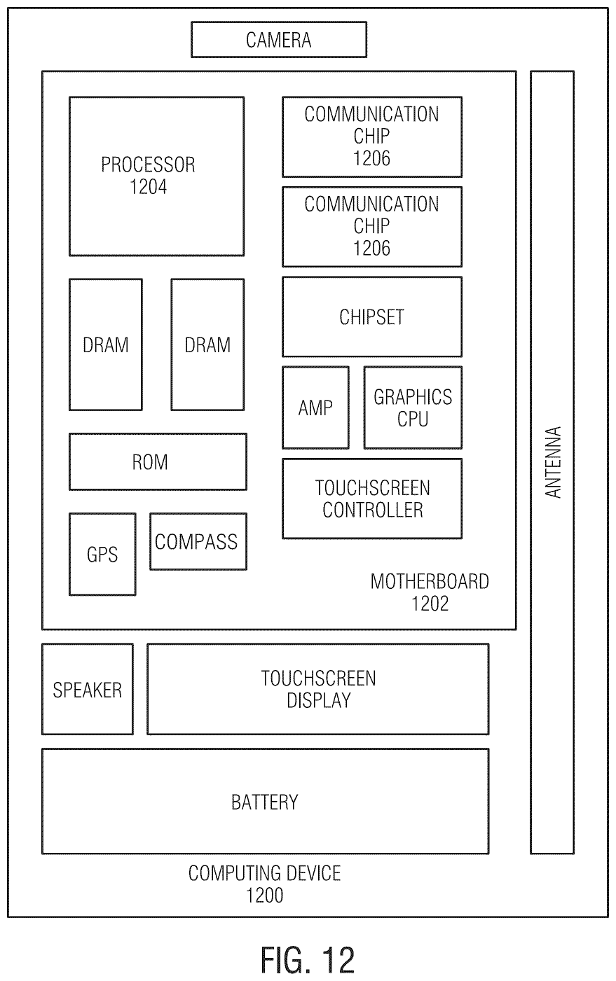

Further details and aspects are mentioned in connection with the examples described above or below. The example shown in FIG. 11 may include one or more optional additional features corresponding to one or more aspects mentioned in connection with the proposed concept or one or more examples described above (e.g., FIGS. 1-11) or below (e.g., FIG. 12).

FIG. 12 illustrates a computing device 1200 in accordance with one implementation of the memory module. The computing device 1200 houses a board 1202. The board 1202 may include a number of components, including but not limited to a processor 1204 and at least one communication chip 1206. The processor 1204 is physically and electrically coupled to the board 1202. In some implementations the at least one communication chip 1206 is also physically and electrically coupled to the board 1202. In further implementations, the communication chip 1206 is part of the processor 1204. Depending on its applications, computing device 1200 may include other components that may or may not be physically and electrically coupled to the board 1202. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). The communication chip 1206 enables wireless communications for the transfer of data to and from the computing device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip $B06 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1200 may include a plurality of communication chips 1206. For instance, a first communication chip 1206 may be dedicated to shorter range wireless communications such as Wi-Fi and Bluetooth and a second communication chip 1206 may be dedicated to longer range wireless communications such as GPS, EDGE, GPRS, CDMA, WiMAX, LTE, Ev-DO, and others. The processor 1204 of the computing device 1200 includes an integrated circuit die packaged within the processor 1204. In some implementations of the invention, the integrated circuit die of the processor includes one or more devices that are assembled in an ePLB or eWLB based POP package that that includes a mold layer directly contacting a substrate, in accordance with implementations of the invention. The term “processor” may refer to any device or portion of a device that processes electronic data from registers and/or memory to transform that electronic data into other electronic data that may be stored in registers and/or memory. The communication chip 1206 also includes an integrated circuit die packaged within the communication chip 1206. In accordance with another implementation of the invention, the integrated circuit die of the communication chip includes one or more devices that are assembled in an ePLB or eWLB based POP package that that includes a mold layer directly contacting a substrate, in accordance with implementations of the invention. The computing device 1200 may further comprise a memory module (DRAM) as described above.

Further details and aspects are mentioned in connection with the examples described above. The example shown in FIG. 12 may include one or more optional additional features corresponding to one or more aspects mentioned in connection with the proposed concept or one or more examples described above (e.g., FIGS. 1-11).

In the following, some examples of the proposed concept are presented:

An example (e.g., example 1) relates to a memory module comprising a printed circuit board, PCB, having a first surface and a second surface opposite the first surface, and a connector edge comprising a set of electrical contacts configured for insertion into a memory socket, a plurality of memory devices mounted on each of the first and second surface of the PCB, a first buffer component mounted on the first surface and electrically coupled to a first subset of the memory devices located on the first and second surface of the PCB, a second buffer component mounted on the second surface and electrically coupled to a second subset of the memory devices located on the first and second surface of the PCB, wherein the memory devices on the first and second surfaces are positioned adjacent to the connector edge of the PCB, and the first and second buffer components are positioned opposite the connector edge on the PCB, the PCB comprising a first and a second signal routing layer respectively associated with the first and second surfaces, each signal routing layer comprising a control signal input line from the set of electrical contacts to the respective buffer component, control signal output lines from the buffer component to the plurality of memory devices, and data signal lines from the set of electrical contacts to the plurality of memory devices.

Another example (e.g., example 2) relates to a previous example (e.g., example 1) or to any other example, further comprising that each buffer component comprises a control signal input and a plurality of control signal outputs, each control signal output being coupled to a respective memory device. 3. The memory module according to any one of examples 1 to 2, wherein the memory devices are arranged in ×12 packages.

Another example (e.g., example 4) relates to a previous example (e.g., one of the examples 1 to 3) or to any other example, further comprising that the memory devices are dynamic random-access memory, DRAM, devices.

Another example (e.g., example 5) relates to a previous example (e.g., one of the examples 1 to 4) or to any other example, further comprising that the memory devices are configured for operation according to a double data rate (DDR) memory protocol, including DDR4, DDR5, or DDR6.

Another example (e.g., example 6) relates to a previous example (e.g., one of the examples 1 to 5) or to any other example, further comprising that the memory module is configured for installation in a memory socket on a system board dimensioned to fit within a 19-inch equipment rack form factor.

Another example (e.g., example 7) relates to a previous example (e.g., one of the examples 1 to 6) or to any other example, further comprising that the memory module and/or the PCB have a module length of 80 millimeters or less. 8. The memory module according to any one of examples 1 to 7, wherein the memory module and/or the PCB have a module length of less than 80 millimeters, thereby enabling two such memory modules to be installed in vertically adjacent memory sockets within the width constraints of a standard 19-inch equipment rack form factor.

Another example (e.g., example 9) relates to a previous example (e.g., one of the examples 1 to 8) or to any other example, further comprising that each memory device package comprises data terminals located along a first edge of the memory device package and control terminals located adjacent to the data terminals.

Another example (e.g., example 10) relates to a previous example (e.g., one of the examples 1 to 9) or to any other example, further comprising that each buffer component comprises one control signal input port and five control signal output ports.

Another example (e.g., example 11) relates to a previous example (e.g., one of the examples 1 to 10) or to any other example, further comprising that at least one of the buffer components is a registered clock driver, RCD.

Another example (e.g., example 12) relates to a previous example (e.g., one of the examples 1 to 11) or to any other example, further comprising a power management integrated circuit, PMIC, mounted on the first surface or the second surface of the PCB.

Another example (e.g., example 13) relates to a previous example (e.g., one of the examples 1 to 12) or to any other example, further comprising that the PCB comprises no more than ten conductive layers.

Another example (e.g., example 14) relates to a previous example (e.g., one of the examples 1 to 13) or to any other example, further comprising that the memory module is a registered dual inline memory module, RDIMM.

Another example (e.g., example 15) relates to a previous example (e.g., one of the examples 1 to 14) or to any other example, further comprising that each buffer component is electrically coupled to at least one memory device mounted on the surface of the PCB opposite to the surface on which the buffer component is mounted.

Another example (e.g., example 16) relates to a previous example (e.g., example 15) or to any other example, further comprising that each buffer component is electrically coupled to the memory device located nearest to the buffer component on the opposite surface.

Another example (e.g., example 17) relates to a previous example (e.g., one of the examples 1 to 16) or to any other example, further comprising that the PCB has a reduced module width relative to a standard RDIMM form factor, enabling placement of two memory modules side by side within the width of a conventional dual-slot server system.

Another example (e.g., example 18) relates to a previous example (e.g., one of the examples 1 to 17) or to any other example, further comprising that five memory devices are mounted on the first surface and five memory devices are mounted on the second surface of the PCB.

Another example (e.g., example 19) relates to a previous example (e.g., one of the examples 1 to 18) or to any other example, further comprising that the memory devices are positioned such that a shortest routing distance from the connector edge to a data terminal of a memory device is no greater than 20 millimeters.

Another example (e.g., example 20) relates to a previous example (e.g., one of the examples 1 to 19) or to any other example, further comprising that the set of electrical contacts on the connector edge comprises at least 120 data signal contacts.

Another example (e.g., example 21) relates to a previous example (e.g., one of the examples 1 to 20) or to any other example, further comprising that the set of electrical contacts on the connector edge comprises a contact pitch configured to provide at least 3 electrical contacts per millimeter of edge length.

An example (e.g., example 22) relates to a system board comprising at least one memory socket, the memory module according to any one of examples 1 to 21, being configured for installation into the memory socket.

Another example (e.g., example 23) relates to a previous example (e.g., example 22) or to any other example, further comprising that the wherein the PCB has a module length of less than 80 millimeters, thereby enabling two such memory modules to be installed in vertically adjacent memory sockets within the width constraints of a 19-inch equipment rack mounting width.

Another example (e.g., example 23) relates to an equipment rack having a 19 inch mounting width, the equipment rack comprising the system board according to examples 22 or 23.

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor or other programmable hardware component. Thus, steps, operations or processes of different ones of the methods described above may also be executed by programmed computers, processors or other programmable hardware components. Examples may also cover program storage devices, such as digital data storage media, which are machine-, processor- or computer-readable and encode and/or contain machine-executable, processor-executable or computer-executable programs and instructions. Program storage devices may include or be digital storage devices, magnetic storage media such as magnetic disks and magnetic tapes, hard disk drives, or optically readable digital data storage media, for example. Other examples may also include computers, processors, control units, (field) programmable logic arrays ((F) PLAs), (field) programmable gate arrays ((F) PGAs), graphics processor units (GPU), application-specific integrated circuits (ASICs), integrated circuits (ICs) or system-on-a-chip (SoCs) systems programmed to execute the steps of the methods described above.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

As used herein, the term “module” refers to logic that may be implemented in a hardware component or device, software or firmware running on a processing unit, or a combination thereof, to perform one or more operations consistent with the present disclosure. Software and firmware may be embodied as instructions and/or data stored on non-transitory computer-readable storage media. As used herein, the term “circuitry” can comprise, singly or in any combination, non-programmable (hardwired) circuitry, programmable circuitry such as processing units, state machine circuitry, and/or firmware that stores instructions executable by programmable circuitry. Modules described herein may, collectively or individually, be embodied as circuitry that forms a part of a computing system. Thus, any of the modules can be implemented as circuitry. A computing system referred to as being programmed to perform a method can be programmed to perform the method via software, hardware, firmware, or combinations thereof.

Any of the disclosed methods (or a portion thereof) can be implemented as computer-executable instructions or a computer program product. Such instructions can cause a computing system or one or more processing units capable of executing computer-executable instructions to perform any of the disclosed methods. As used herein, the term “computer” refers to any computing system or device described or mentioned herein. Thus, the term “computer-executable instruction” refers to instructions that can be executed by any computing system or device described or mentioned herein.

The computer-executable instructions can be part of, for example, an operating system of the computing system, an application stored locally to the computing system, or a remote application accessible to the computing system (e.g., via a web browser). Any of the methods described herein can be performed by computer-executable instructions performed by a single computing system or by one or more networked computing systems operating in a network environment. Computer-executable instructions and updates to the computer-executable instructions can be downloaded to a computing system from a remote server.

Further, it is to be understood that implementation of the disclosed technologies is not limited to any specific computer language or program. For instance, the disclosed technologies can be implemented by software written in C++, C#, Java, Perl, Python, JavaScript, Adobe Flash, C#, assembly language, or any other programming language. Likewise, the disclosed technologies are not limited to any particular computer system or type of hardware.

Furthermore, any of the software-based examples (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, cable (including fiber optic cable), magnetic communications, electromagnetic communications (including RF, microwave, ultrasonic, and infrared communications), electronic communications, or other such communication means.

The disclosed methods, apparatuses, and systems are not to be construed as limiting in any way. Instead, the present disclosure is directed toward all novel and nonobvious features and aspects of the various disclosed examples, alone and in various combinations and subcombinations with one another. The disclosed methods, apparatuses, and systems are not limited to any specific aspect or feature or combination thereof, nor do the disclosed examples require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

What is claimed is:

1. A memory module comprising: a printed circuit board, PCB, having a first surface and a second surface opposite the first surface, and a connector edge comprising a set of electrical contacts configured for insertion into a memory socket;
a plurality of memory devices mounted on each of the first and second surface of the PCB;
a first buffer component mounted on the first surface and electrically coupled to a first subset of the memory devices located on the first and second surface of the PCB;
a second buffer component mounted on the second surface and electrically coupled to a second subset of the memory devices located on the first and second surface of the PCB,
wherein the memory devices on the first and second surfaces are positioned adjacent to the connector edge of the PCB, and the first and second buffer components are positioned opposite the connector edge on the PCB,
the PCB comprising a first and a second signal routing layer respectively associated with the first and second surfaces, each signal routing layer comprising a control signal input line from the set of electrical contacts to the respective buffer component, control signal output lines from the buffer component to the plurality of memory devices, and data signal lines from the set of electrical contacts to the plurality of memory devices.

2. The memory module of claim 1, wherein each buffer component comprises a control signal input and a plurality of control signal outputs, each control signal output being coupled to a respective memory device.

3. The memory module according to claim 1, wherein the memory devices are arranged in ×12 packages.

4. The memory module according to claim 1, wherein the memory devices are dynamic random-access memory, DRAM, devices.

5. The memory module according to claim 1, wherein the memory devices are configured for operation according to a double data rate (DDR) memory protocol, including DDR4, DDR5, or DDR6.

6. The memory module according to claim 1, wherein the memory module is configured for installation in a memory socket on a system board dimensioned to fit within a 19-inch equipment rack form factor.

7. The memory module according to claim 1, wherein the memory module and/or the PCB have a module length of 80 millimeters or less.

8. The memory module according to claim 1, wherein the memory module and/or the PCB have a module length of less than 80 millimeters, thereby enabling two such memory modules to be installed in vertically adjacent memory sockets within the width constraints of a standard 19-inch equipment rack form factor.

9. The memory module according to claim 1, wherein each memory device package comprises data terminals located along a first edge of the memory device package and control terminals located adjacent to the data terminals.

10. The memory module according to claim 1, wherein each buffer component comprises one control signal input port and five control signal output ports.

11. The memory module according to claim 1, wherein at least one of the buffer components is a registered clock driver, RCD.

12. The memory module according to claim 1, further comprising a power management integrated circuit, PMIC, mounted on the first surface or the second surface of the PCB.

13. The memory module according to claim 1, wherein the PCB comprises no more than ten conductive layers.

14. The memory module according to claim 1, wherein the memory module is a registered dual inline memory module, RDIMM.

15. The memory module according to claim 1, wherein each buffer component is electrically coupled to at least one memory device mounted on the surface of the PCB opposite to the surface on which the buffer component is mounted.

16. The memory module according to claim 15, wherein each buffer component is electrically coupled to the memory device located nearest to the buffer component on the opposite surface.

17. The memory module according to claim 1, wherein the PCB has a reduced module width relative to a standard RDIMM form factor, enabling placement of two memory modules side by side within the width of a conventional dual-slot server system.

18. The memory module according to claim 1, wherein five memory devices are mounted on the first surface, and five memory devices are mounted on the second surface of the PCB.

19. The memory module according to claim 1, wherein the memory devices are positioned such that a shortest routing distance from the connector edge to a data terminal of a memory device is no greater than 20 millimeters.

20. A system board comprising:
at least one memory socket;
the memory module according to claim 1, being configured for installation into the memory socket.
